(19) United States
(12) Patent Application Publication
(10) Pub. No.: US 2008/0297992 A1
(43) Pub. Date: Dec. 4, 2008

(54) HOLLOW SEALING STRUCTURE AND MANUFACTURING METHOD FOR HOLLOW SEALING STRUCTURE

(76) Inventors: Susumu OBATA, Yokohama-shi (JP); Michinobu Inoue, Yokohama-shi (JP); Takeshi Miyagi, Fujisawa-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/128,956

(22) Filed: May 29, 2008

(30) Foreign Application Priority Data
May 31, 2007 (JP) 2007-145895

(51) Int. Cl. H05K 7/00; H01L 21/00

(52) U.S. Cl. 361/679; 438/106; 257/E21.499

(57) ABSTRACT

A hollow sealing structure includes, a substrate, a functional element portion disposed on a principal surface of the substrate, and a covering portion disposed over the principal surface of the substrate to form a hollow portion in which the covering portion covers the functional element portion, the covering portion including a first covering structure portion having a plurality of openings, second covering structure portions disposed individually on imaginary straight lines which connect the functional element portion and the openings, and a sealing structure portion which seals gaps defined between the first covering structure portion and the second covering structure portions.

### CROSS-REFERENCE TO RELATED APPLICATIONS

This application is based upon and claims the benefit of priority from prior Japanese Patent Application No. 2007-145895, filed May 31, 2007, the entire contents of which are incorporated herein by reference.

### BACKGROUND OF THE INVENTION

1. Field of the Invention

The present invention relates to a hollow sealing structure for a functional element, such as a microelectric machine part, micromachine packaging, etc., and a manufacturing method for the hollow sealing structure.

2. Description of the Related Art

There are known hollow sealing structures, such as an electric machine part for sealing a functional element mounted on a substrate in a hollow space. For example, a hollow sealing structure 21 shown in FIG. 15 is composed of a base substrate 22, a dielectric layer 23, a functional element 24, a signal conducting member 25, a gap portion 26, and first and second sealing members 27 and 28 as sealing members.

The functional element 24 has, for example, a doubly-supported beam structure such that the central part of a beam is separated from the signal conducting member 25 by several micrometers. The signal conducting member 25 of Au or the like is formed on the dielectric layer 23 immediately under the functional element 24. The functional element 24 is formed of TiN or Al with high elasticity. If it is subjected to a driving force, such as an electrostatic force, the functional element 24 is deformed so as to approach the signal conducting member 25. If the driving force is removed, the functional element 24 is restored to its original position by its own elasticity. Thus, the functional element 24 fulfills functions, such as variable capacitance change, switching, etc., as the distance from the signal conducting member 25 changes depending on the driving force.

A technique for sealing the functional element 24 in a hollow space is described in, for example, Jpn. Pat. Appln. KOKAI Publication No. 2005-207959. According to this technique, a thin film prepared by a film forming process is used to reduce the manufacturing cost and size of the element. As shown in FIG. 10, a sacrificial layer (first layer) 32 is formed on a substrate that is composed of the base substrate 22 and the dielectric layer 23. Then, the functional element 24 is formed on the sacrificial layer 32, as shown in FIG. 11. As shown in FIG. 12, a sacrificial layer (second layer) 33 is formed on the functional element 24 that is formed on the sacrificial layer 32. As shown in FIG. 13, opening portions 27a for the introduction of an etching material for sacrificial layer removal are formed in the first sealing member 27.

Normally, in order to prevent a film material from depositing on the functional element when the second sealing member 28 (mentioned later) is prepared by a film forming method, such as sputtering, vapor deposition, or CVD, the opening portions 27a are spaced from the functional element. Further, spaces for the circulation of the etching material for sacrificial layer removal must be secured between the upper surface of the dielectric layer 23 and those parts of the lower surface of the first sealing member 27 which are situated near the opening portions 27a. Then, the sacrificial layers 32 and 33 are thoroughly removed by introducing the etching material for sacrificial layer removal through the opening portions 27a, as shown in FIG. 14. Finally, the opening portions 27a are closed by forming the second sealing member 28 on the first sealing member 27. Thereupon, a hollow sealing structure is completed such that the functional element is sealed in the hollow space.

However, the above-described technique involves the following problems. In the aforesaid structure, the first sealing member must be made large enough to secure the circulation of the etching material for sacrificial layer removal. Accordingly, the hollow sealing structure and the sacrificial layers therein are increased in size, and the removal of the sacrificial layers takes longer, so that the productivity is low.

The present invention has been made in order to solve these problems, and its object is to provide a high-yield hollow sealing structure and a manufacturing method for the hollow sealing structure.

### BRIEF SUMMARY OF THE INVENTION

According to an aspect of the invention, a hollow sealing structure comprises, a substrate, a functional element portion disposed on a principal surface of the substrate, and a covering portion disposed over the principal surface of the substrate to form a hollow portion in which the covering portion covers the functional element portion, the covering portion including a first covering structure portion having a plurality of openings, second covering structure portions disposed individually on imaginary straight lines which connect the functional element portion and the openings, and a sealing structure portion which seals gaps defined between the first covering structure portion and the second covering structure portions.

According to another aspect of the invention, a hollow sealing structure, wherein each of the second covering structure portions includes a support portion supported on a peripheral edge of the opening on an outer surface of the first covering structure portion and a lid portion which is supported on the support portion and covers the opening from outside with respect to the direction of the imaginary straight line, a part of the lid portion being spaced from the peripheral edge of the opening on the outer surface of the first covering structure portion, the gap being formed in the spaced portion.

According to another aspect of the invention, a manufacturing method for a hollow sealing structure comprises, a process for disposing a functional element portion on a principal surface of a substrate, a process for forming a first sacrificial layer on the functional element portion, a process for forming, on the first sacrificial layer and the principal surface of the substrate, a first covering structure portion having a plurality of openings and second covering structure portions disposed individually on imaginary straight lines which connect the functional element portion and the openings, a process for removing the first sacrificial layer by introducing a fluid for sacrificial layer removal through gap portions defined between the first covering structure portion and the second covering structure portions, and a process for forming a sealing structure portion which seals gaps defined between the first covering structure portion and the second covering structure portions.

According to another aspect of the invention, a manufacturing method for a hollow sealing structure, comprises, a process for disposing a functional element portion on a principal surface of a substrate, a process for forming a first sacrificial layer on the functional element portion, a process for forming a first covering structure portion having a plurality of openings on the first sacrificial layer and the principal surface of the substrate, a process for forming support portions supported on respective peripheral edges of the openings on an outer surface of the first covering structure portion, a process for forming a second sacrificial layer on the first sacrificial layer corresponding to the openings of the first covering structure portion, a process for forming on the second sacrificial layer lid portions which are supported on the support portions and cover the openings from outside with respect to the imaginary straight lines which connect the functional element portion and the openings, a process for removing the first and second sacrificial layers by introducing a fluid for sacrificial layer removal through gap portions defined between the first covering structure portion and the lid portions, and a process for forming a sealing structure portion which seals the gap portions defined between the first covering structure portion and the lid portions.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawing, which are incorporated in and constitute a part of the specification, illustrate embodiments of the invention, and together with the detailed description of the embodiments given below, serve to explain the principles of the invention.

FIG. 1 is a perspective view, partially in section, showing a hollow sealing structure according to an embodiment of the invention;

FIG. 2 is a plan view of the hollow sealing structure;

FIG. 3 is a sectional view of the hollow sealing structure;

FIG. 4 is a sectional view showing a manufacturing process for the hollow sealing structure;

FIG. 5 is a sectional view showing a manufacturing process for the hollow sealing structure;

FIG. 6 is a sectional view showing a manufacturing process for the hollow sealing structure;

FIG. 7 is a sectional view showing a manufacturing process for the hollow sealing structure;

FIG. 8 is a sectional view showing a manufacturing process for the hollow sealing structure;

FIG. 9 is a sectional view showing a manufacturing process for the hollow sealing structure;

FIG. 10 is a sectional view showing an example of a manufacturing process for a hollow sealing structure;

FIG. 11 is a sectional view showing an example of a manufacturing process for the hollow sealing structure;

FIG. 12 is a sectional view showing an example of a manufacturing process for the hollow sealing structure;

FIG. 13 is a sectional view showing an example of a manufacturing process for the hollow sealing structure;

FIG. 14 is a sectional view showing an example of a manufacturing process for the hollow sealing structure; and

FIG. 15 is a sectional view showing an example of the hollow sealing structure.

### DETAILED DESCRIPTION OF THE INVENTION

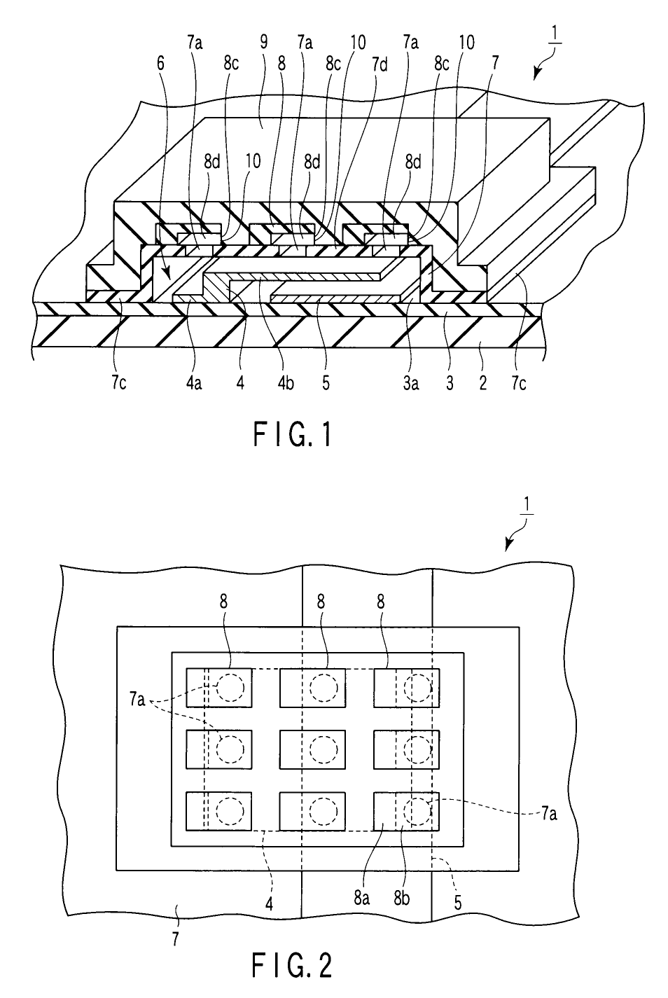

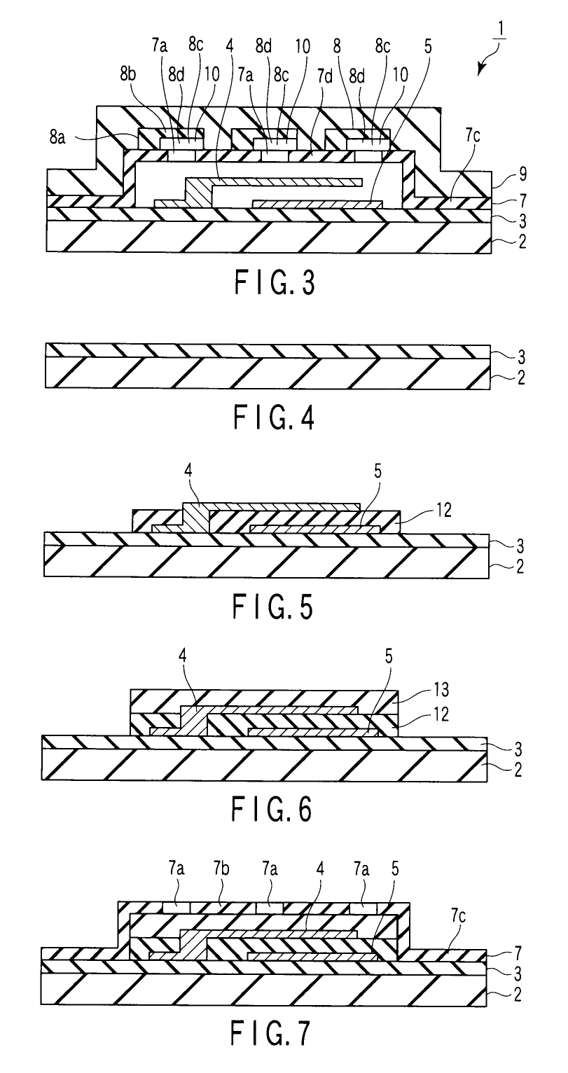

A sealing structure according to a first embodiment of the present invention will now be described with reference to FIGS. 1 and 3. In each of these drawings, configurations are schematically shown in an enlarged or reduced scale or omitted as required. A sealing structure portion 9 is not shown in FIG. 2.

A hollow sealing structure 1 is a microelectric machine part, for example. It is composed of a base substrate 2, a dielectric layer 3, a functional element (functional element portion) 4, a signal conducting member 5, and a hollow portion 6. Further, the sealing structure 1 includes first and second covering structure portions 7 and 8, for use as covering portions, and the sealing structure portion 9.

The base substrate 2 is formed of a plate of, for example, silicon (Si).

The dielectric layer 3, which is formed on the base substrate 2, is a film of silicon oxide (SiO₂), for example. The base substrate 2 and the dielectric layer 3 constitute a substrate.

The signal conducting member 5 and the functional element 4 are formed on an upper surface 3a of the dielectric layer 3. The signal conducting member 5 is formed of Au or the like and has a rectangular shape that extends in a Y-direction as illustrated in the drawings.

The functional element 4 is formed on the upper surface 3a of the dielectric layer 3. The functional element 4 is a micromachine that includes a movable mechanism and has the form of a cantilever with a step. It is provided integrally with a support portion 4a and a beam portion 4b with the step between them. The support portion 4a is supported by the upper surface 3a of the dielectric layer 3, and the beam portion 4b as a movable portion extends horizontally from the upper end portion of the support portion 4a. The beam portion 4b is several micrometers above the signal conducting member 5. The functional element 4 is formed of TiN or Al with high elasticity. If it is subjected to a driving force, such as an electrostatic force, the functional element 4 approaches the signal conducting member 5. If the driving force is removed, the functional element 4 is restored to its original position by its own elasticity. Thus, the functional element 4 fulfills functions, such as variable capacitance change, switching, etc., as it is deformed so that the distance from the signal conducting member 5 changes depending on the driving force.

The first covering structure portion 7 is formed integrally with a support portion 7c and a cover portion 7d. The support portion 7c is situated around the functional element 4. The cover portion 7d covers the functional element 4 from above with the hollow portion 6 therebetween. The support portion 7c of the first covering structure portion 7 is supported on the upper surface of the dielectric layer 3.

The cover portion 7d is provided with a plurality of openings 7a that are vertically penetrated by the first covering structure portion 7. The openings 7a are arranged over the functional element 4.

Each second covering structure portion 8 is formed near each corresponding one of the openings 7a. The second covering structure portion 8 is provided with a rectangular sidewall portion 8a, for use as a support portion, and a rectangular lid portion 8b. The sidewall portion 8a extends in the Z-direction in the figures from the upper surface (outer surface) of the cover portion 7d of the first covering structure portion 7. The lid portion 8b extends in the Y-direction from the upper end of the sidewall portion 8a. Thus, the sidewall portion 8a has an L-shaped cross section.

The lid portion 8b includes an overlying spaced portion that is spaced from the upper surface (outer surface) of the cover portion 7d near each opening 7a. Thus, the lid portion 8b is situated on an imaginary straight line connecting the opening 7a and the functional element 4 and on the outside with respect to the direction of the imaginary straight line. A gap portion 8c that is defined between the lid portion 8b and the outer surface forms a channel 8d through which the opening 7a transversely communicates with the exterior. The channel 8d and the opening 7a constitute an opening portion 10 that opens transversely. A fluid for sacrificial layer removal can be introduced from the opening portion 10 into the first covering structure portion 7 through the channel 8d. According to the present embodiment in which the sealing structure portion 9 is prepared by downward film formation from above, the outside with respect to the direction of deposition is upward. Since the opening 7a is covered by the lid portion 8b from above, the sealing structure portion 9 can be prevented from penetrating into and depositing in the hollow portion 6 through the opening portion 10 when the sealing structure portion 9 is formed.

The sealing structure portion 9 is formed on the first covering structure portion 7 so as to cover it from outside. The sealing structure portion 9 hermetically closes the hollow portion 6 inside the first covering structure portion 7, whereby the functional element 4 is sealed in a hollow space.

A manufacturing method for the hollow sealing structure 1 according to the present embodiment will now be described with reference to FIGS. 4 to 9.

First, as shown in FIG. 4, the dielectric layer 3 is formed on the base substrate 2, and the signal conducting member 5 is formed on the base substrate 2.

Then, an electrostatically-driven high-frequency switch is formed as the functional element 4 having a cantilever structure using, for example, gold (Au) as a component material. When this is done, a sacrificial layer 12 of a predetermined shape is first formed on the signal conducting member 5, and the functional element 4 is then formed on the sacrificial layer 12 with a step, as shown in FIG. 5. Thereupon, the functional element 4 is formed in a predetermined shape having the support portion 4a and the beam portion 4b, as well as the step.

As shown in FIG. 6, moreover, a sacrificial layer 13 (first sacrificial layer) is formed using, for example, polycrystalline silicon, which can be removed by a reactive gas, so as to cover the functional element 4.

As shown in FIG. 7, the first covering structure portion 7 is formed using, for example, a silicon nitride film on the sacrificial layer 13. When this is done, the vertically penetrating openings 7a are formed by patterning. Thus, the sacrificial layer 13 is not covered by the first covering structure portion 7 in positions corresponding to the openings 7a.

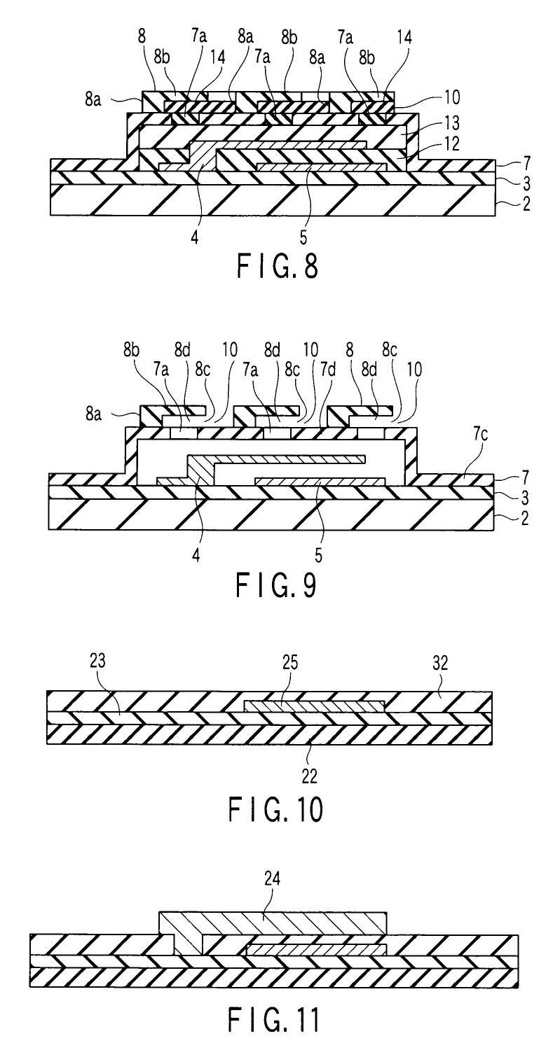

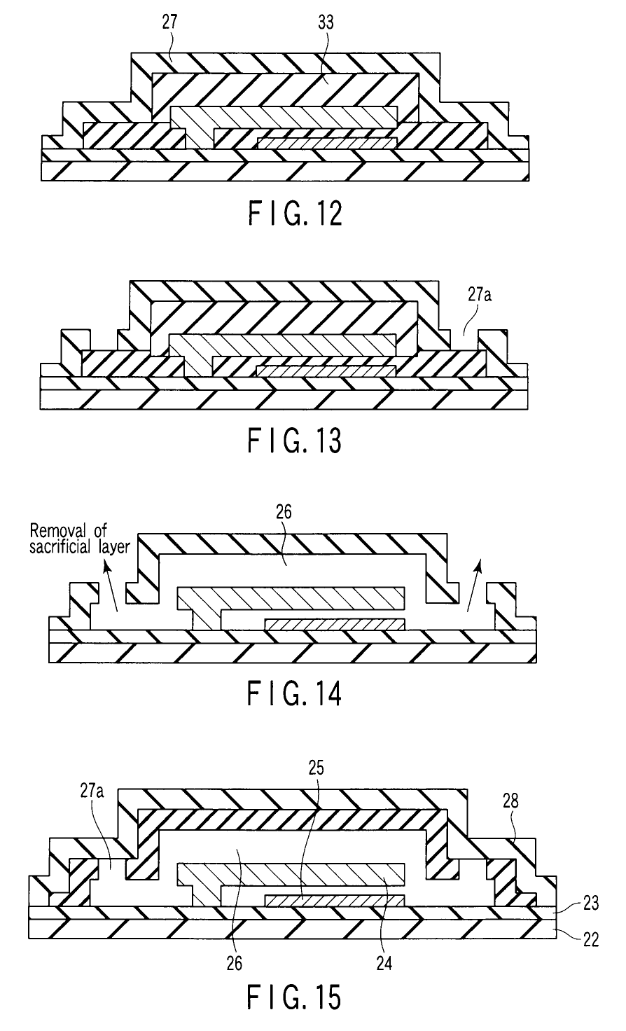

Then, as shown in FIG. 8, a sacrificial layer 14 (second sacrificial layer) of a predetermined height is formed so as to fill the openings 7a and cover their peripheries.

As shown in FIG. 8, the second covering structure portion 8, like the first covering structure portion 7, is formed using, for example, a silicon nitride film on the sacrificial layer 14. When this is done, the L-shaped second covering structure portion 8 is formed having the sidewall portion 8a, lid portion 8b, and gap portion 8c by forming the film to cover the sacrificial layer 14.

Then, the sacrificial layers 12, 13 and 14 are removed through the gap portions 8c, as shown in FIG. 8. The sacrificial layers 14, 13 and 12 are removed by introducing, for example, XeF₂ gas, which selectively removes polycrystalline silicon, through the transverse opening portions 10 that are formed transversely communicating with the gap portions 8c and the openings 7a. In consequence, a gap is formed in each opening portion 10, and the hollow portion 6 is formed inside the first covering structure portion 7.

After the gap portion 6 is formed, a silicon nitride (SiN) film that is thick enough to fill the openings 7a is deposited from above the first covering structure portion 7 to form the sealing structure portion 9 by a film forming process, such as sputtering, vapor deposition, or CVD. Since the openings 7a are covered from above when this is done, the sealing structure portion 9 can be prevented from depositing in the hollow portion 6. More specifically, the transverse direction in which the opening portions 10 open is perpendicular to an upward direction or processing direction for the sealing structure portion 9, so that the sealing structure portion 9 can be prevented from penetrating the interior through the opening portions 10.

Thus, the gaps in the opening portions 10 are sealed by the sealing structure portion 9 so that the openings 7a are hermetically closed, and the functional element 4 in the hollow portion 6 is sealed by the first covering structure portion 7 and the sealing structure portion 9, whereupon the hollow sealing structure 1 shown in FIGS. 1 to 3 is completed.

The hollow sealing structure 1 according to the present embodiment and its manufacturing method produce the following effects.

With use of the covering portions constructed in this manner, the openings for sacrificial layer removal can be located near the functional element 4. Therefore, the covering portions can be reduced in overall size, the speed of removal of the sacrificial layers in the hollow portion can be increased considerably, and the openings can be sealed after the removal of the sacrificial layers without changing the construction of the functional element, so that the productivity can be improved. Thus, according to the present embodiment, a gas or liquid for sacrificial layer removal can be introduced into the first covering structure portion 7 through the gap portions 8c, and the openings 7a are covered by the lid portions 8b from above or from the outside with respect to the direction of deposition. In forming the sealing structure portion 9, according to this arrangement, the sealing structure portion 9 can be prevented from penetrating the interior through the openings 7a. Thus, the openings 7a can be located above the functional element 4, and a space between the first covering structure portion 7 and the principal surface of the dielectric layer, which used to be provided for securing passages for the gas or liquid for sacrificial layer removal, can be omitted. Therefore, the entire hollow sealing structure can be reduced in overall size and miniaturized. Further, the sacrificial layers therein can be reduced in number, and the time for the removal of the sacrificial layers can be shortened.

The present invention is not limited to the embodiment described above, and the materials, shapes, layouts, sizes, constructions, operations, etc., of its component elements may be modified as required. Examples of patterning methods and methods for sacrificial layer removal include dry etching with an etching gas, wet etching with chemicals, etc. Further, the sacrificial layers need not always be identical. The above-described structure is provided with the substrate that is composed of the base substrate 2 and the dielectric layer 3 thereon. Alternatively, however, the dielectric layer 3 may be omitted so that the substrate is composed of the base substrate 2 only. In this case, the functional element 4, signal conducting member 5, and first covering structure portion are formed on the base substrate 2. Further, the first covering structure portion 7, second covering structure portion 8, and sealing structure portion 9 may be formed of any of filmable, patternable materials, including organic materials, inorganic materials, and metals.

In the manufacturing method according to the first embodiment described herein, moreover, the structure has an L-shaped cross section such that the second covering structure portion 8 includes the sidewall portion 8a and the lid portion 8b. However, the structure of the present invention is not limited to this shape, but may be formed having a U-shaped cross section. Further, the invention is also applicable to a dome-shaped structure with a transverse gap.

In carrying out the invention, moreover, its components may be embodied in modified forms without departing from the scope or spirit of the invention. Further, various inventions may be made by suitably combining a plurality of components described in connection with the foregoing embodiment. For example, some of the components according to the foregoing embodiment may be omitted. Furthermore, components according to different embodiments may be combined as required.

Additional advantages and modifications will readily occur to those skilled in the art. Therefore, the invention in its broader aspects is not limited to the specific details and representative embodiments shown and described herein. Accordingly, various modifications may be made without departing from the spirit or scope of general inventive concept as defined by appended claims and their equivalents.

What is claimed is:

1. A hollow sealing structure comprising:
a substrate;
a functional element portion disposed on a principal surface of the substrate; and
a covering portion disposed over the principal surface of the substrate to form a hollow portion in which the covering portion covers the functional element portion,
the covering portion including a first covering structure portion having a plurality of openings, second covering structure portions disposed individually on imaginary straight lines which connect the functional element portion and the openings, and a sealing structure portion which seals gaps defined between the first covering structure portion and the second covering structure portions.

2. A hollow sealing structure according to claim 1, wherein each of the second covering structure portions includes a support portion supported on a peripheral edge of the opening on an outer surface of the first covering structure portion and a lid portion which is supported on the support portion and covers the opening from outside with respect to the direction of the imaginary straight line, a part of the lid portion being spaced from the peripheral edge of the opening on the outer surface of the first covering structure portion, the gap being formed in the spaced portion.

3. A manufacturing method for a hollow sealing structure, comprising:
a process for disposing a functional element portion on a principal surface of a substrate;
a process for forming a first sacrificial layer on the functional element portion;
a process for forming, on the first sacrificial layer and the principal surface of the substrate, a first covering structure portion having a plurality of openings and second covering structure portions disposed individually on imaginary straight lines which connect the functional element portion and the openings;
a process for removing the first sacrificial layer by introducing a fluid for sacrificial layer removal through gap portions defined between the first covering structure portion and the second covering structure portions; and
a process for forming a sealing structure portion which seals gaps defined between the first covering structure portion and the second covering structure portions.

4. A manufacturing method for a hollow sealing structure, comprising:
a process for disposing a functional element portion on a principal surface of a substrate;
a process for forming a first sacrificial layer on the functional element portion;
a process for forming a first covering structure portion having a plurality of openings on the first sacrificial layer and the principal surface of the substrate;
a process for forming support portions supported on respective peripheral edges of the openings on an outer surface of the first covering structure portion;
a process for forming a second sacrificial layer on the first sacrificial layer corresponding to the openings of the first covering structure portion;
a process for forming on the second sacrificial layer lid portions which are supported on the support portions and cover the openings from outside with respect to imaginary straight lines which connect the functional element portion and the openings;
a process for removing the first and second sacrificial layers by introducing a fluid for sacrificial layer removal through gap portions defined between the first covering structure portion and the lid portions; and
a process for forming a sealing structure portion which seals the gap portions defined between the first covering structure portion and the lid portions.
